(19) United States
(12) Patent Application Publication
(10) Pub. No.: US 2004/0163590 A1
(43) Pub. Date: Aug. 26, 2004

(54) In-situ health check of liquid injection vaporizer

(75) Inventors: Toan Tran, San Jose, CA (US); Yen-Kun Wang, Fremont, CA (US); Steve Ghanayem, Los Altos, CA (US); Sean Herbert, San Carlos, CA (US); Won B. Bang, Santa Clara, CA (US)

Correspondence Address: Patent Counsel, APPLIED MATERIALS, INC., Legal Affairs Department,, P.O. Box 450A, M/S 2061, Santa Clara, CA, 95052, US

(73) Assignee: Applied Materials, Inc., Santa Clara, CA

(21) Appl. No.: 10/374,571

(22) Filed: Feb. 24, 2003

(51) Int. Cl. C23C 16/00

(52) U.S. Cl. 118/715

(57) ABSTRACT

Early detection of clogging of a liquid precursor injection valve in a gas delivery system of a semiconductor fabrication tool is allowed through monitoring pressure upstream of the injection valve. The increase in pressure associated with obstruction of the valve may trigger an alarm alerting the operator, allowing for rapid correction of the problem before substantial numbers of wafers are improperly processed utilizing the clogged valve.

### BACKGROUND OF THE INVENTION

Chemical vapor deposition (CVD) and other processing employed in the fabrication of semiconductor devices may utilize a number of gases. These gases, which may take the form of vaporized liquid precursors, are generated and supplied to a CVD chamber via a system of pipes or lines and vaporizing mechanisms known as a gas delivery system. Typically a separate vaporizing mechanism is provided for vaporizing each processing liquid precursor, and is coupled to a source of processing liquid and a source of carrier gas. Each vaporizing mechanism and processing liquid source combination within a gas delivery system is referred to as a vaporization stage. Although a number of vaporizing mechanisms exist (e.g., bubblers, injection valves, etc.), most conventional gas delivery systems employ a plurality of injection valves for vaporizing processing liquids that are to be delivered to a CVD chamber.

A typical injection valve comprises a processing liquid inlet for receiving a pressurized processing liquid, a carrier gas inlet for receiving a pressurized inert carrier gas, and an outlet for delivering a vaporized processing liquid/carrier gas mixture. The injection valve is heated such that when the processing liquid is injected into the carrier gas, the heat and the low partial vapor pressure of the processing liquid in the carrier gas causes the processing liquid to vaporize. A high carrier gas pressure produces more processing liquid vaporization by lowering the partial vapor pressure of the processing liquid within the carrier gas. Accordingly, when designing a gas delivery system, maintenance of adequate carrier gas pressure is an important consideration, as is minimizing overall system size and complexity.

To achieve a low partial vapor pressure for each processing precursor liquid while minimizing system size, conventional gas delivery systems are configured such that a carrier gas is delivered (via a mass flow controller) to a first injection valve, where it is used to vaporize a first processing liquid, forming a first vaporized processing liquid/carrier gas mixture. Where a second liquid precursor is also utilized in processing, the first vaporized processing liquid/carrier gas mixture may then be delivered in serial to the carrier gas inlet of a second, consecutive injection valve used to vaporize a second processing liquid. Where additional liquid precursors are also employed in processing, a mixture of the first and second vaporized processing liquids and the carrier gas is then delivered in serial to the carrier gas inlet of a third consecutive injection valve, etc.

The gas delivery system configurations just described provide a compact and cost-effective system, as they employ a single gas line and a single carrier gas source controlled by a single mass flow controller to achieve vaporization within each of the various vaporization stages. Additionally, conventional gas delivery systems facilitate vaporization of liquid precursors, as the entire mass flow of the carrier gas is applied to each injection valve in the series.

Despite their overall compact and efficient design, the maintenance and proper operation of conventional gas delivery systems may be expensive. For example, the orifices in the injection valve through which the carrier gas flows and through which the liquid precursor flows are narrow and prone to clogging. Solid material which can obstruct these narrow passageways in the injection valve may result from the presence of impurities or moisture in the metal tubing, liquid precursor, or carrier gas.

Unfortunately, conventional gas delivery systems do not include a sensor warning of clogging of the injection valve. Instead, clogging of an injection valve is generally detectable only indirectly, by observation of defects in wafers resulting from incomplete exposure to the vaporized liquid precursor, which has been blocked by the obstructed injection valve. This after-the-fact indication of injection valve clogging can be expensive, as entire lots of processed wafers may need to be scrapped.

Accordingly, a need exists for a gas delivery system for a semiconductor processing tool which allows for the rapid and effective detection of clogging of an injection valve.

### BRIEF SUMMARY OF THE INVENTION

Early detection of clogging of a liquid precursor injection valve in a semiconductor fabrication tool is permitted through monitoring of pressure upstream of the valve. The increase in pressure associated with obstruction of the valve may trigger alarms which alert the operator and allow rapid correction of the problem, before substantial numbers of wafers are improperly processed utilizing the clogged valve.

A embodiment of a system in accordance with the present invention for providing a vaporized liquid precursor to a semiconductor processing chamber, comprises, a mass flow controller in fluid communication with a pressurized carrier gas source through a carrier gas flow line. A liquid precursor injection valve is in fluid communication with the mass flow controller through the carrier gas flow line, in fluid communication with a liquid precursor source through a first line, and in fluid communication with a processing chamber through a delivery line. A pressure transducer is in communication with the carrier gas flow line and configured to detect a pressure within the carrier gas flow line between the mass flow controller and the injection valve.

An embodiment of an apparatus in accordance with the present invention for processing a semiconductor substrate, comprises, a processing chamber comprising a chamber lid and walls enclosing a substrate support, a gas distributor, and a vacuum exhaust connected to a chamber outlet. A gas delivery system is in fluid communication with the gas distributor, the gas delivery system comprising a mass flow controller in fluid communication with a pressurized carrier gas source through a carrier gas flow line. The gas delivery system also comprises a liquid precursor injection valve in fluid communication with the mass flow controller through the carrier gas flow line, in fluid communication with a liquid precursor source through a first line, and in fluid communication with a processing chamber through a delivery line. The gas delivery system further comprises a pressure transducer in communication with the carrier gas flow line and configured to detect a pressure within the carrier gas flow line between the mass flow controller and the injection valve. The apparatus further comprises a system controller comprises a memory and a processor, the processor in electrical communication with the pressure transducer.

An embodiment of method in accordance with the present invention for detecting clogging of an injection valve providing vaporized liquid precursor material to a semiconductor processing chamber, comprises, detecting a pressure at a point between the injection valve and a mass flow controller providing a carrier gas to the injection valve.

An embodiment of a vaporizing system in accordance with the present invention comprises a liquid injection valve having first and second inlets and an outlet, the injection valve capable of receiving a carrier gas at the first inlet, receiving a liquid precursor at the second inlet, and delivering a mixture of vaporized liquid precursor and carrier gas through the outlet. The vaporizing system further comprises a carrier gas source, a first gas line that couples the carrier gas source to the first inlet, a liquid precursor source, and a second gas line that couples the liquid precursor source to the second inlet. A mass flow controller is operatively coupled to the first gas line. A pressure transducer is coupled to the first gas line between the mass flow controller and the first inlet.

A method of delivering vaporized liquid to a processing chamber comprises separately flowing a carrier gas and a liquid to an injection valve. The liquid is vaporized with the injection valve and the vaporized liquid is combined with the carrier gas. Pressure of the carrier gas upstream of the injection valve is detected, and detected pressure is compared versus a setpoint pressure value.

These and other embodiments of the present invention, as well as its advantages and features, are described in more detail in conjunction with the text below and attached figures.

### BRIEF DESCRIPTION OF THE DRAWINGS

FIG. 1A is a simplified representation of a CVD apparatus according to the present invention.

FIG. 1B is a simplified representation of the user interface for a CVD system in relation to a deposition chamber in a multi-chamber system.

FIG. 1C is a simplified of a block diagram of the hierarchical control structure of the system control software according to a specific embodiment.

FIG. 2 is a schematic diagram of a chemical vapor deposition system including one embodiment of a gas delivery system in accordance with the present invention.

FIG. 3 is a diagrammatic side elevational view of a generic vaporization stage comprising a conventional injection valve useful in describing the preferred embodiment of the invention.

FIG. 4 is a top plan view of an automated tool for semiconductor device fabrication which employs the gas delivery system of FIG. 2.

FIG. 5 is a schematic diagram of a chemical vapor deposition system including a first alternative embodiment of a gas delivery system in accordance with the present invention.

FIG. 6 is a schematic diagram of a chemical vapor deposition system including a second alternative embodiment of a gas delivery system in accordance with the present invention.

FIGS. 7A and 7B plot pressure upstream of an injection valve versus diameter of the orifice through which gas is flowed, for two different conditions of gas flow.

### DESCRIPTION OF THE SPECIFIC EMBODIMENTS

I. Exemplary Deposition System

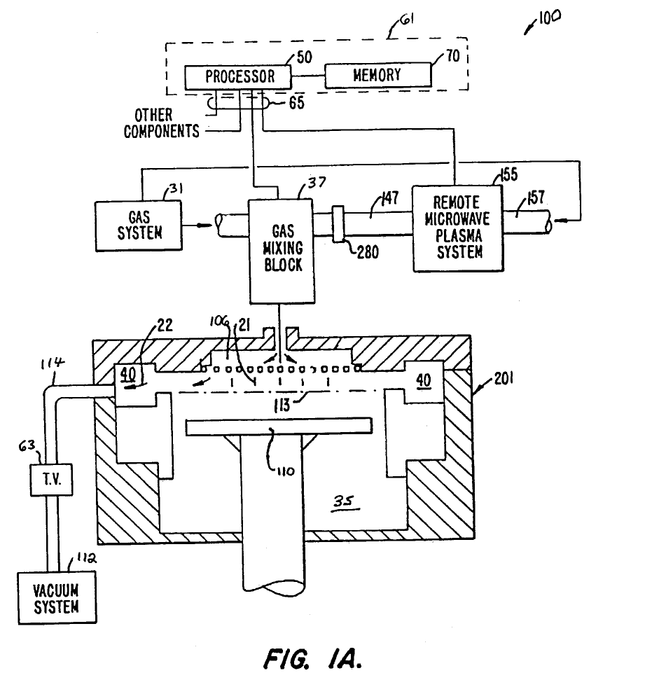

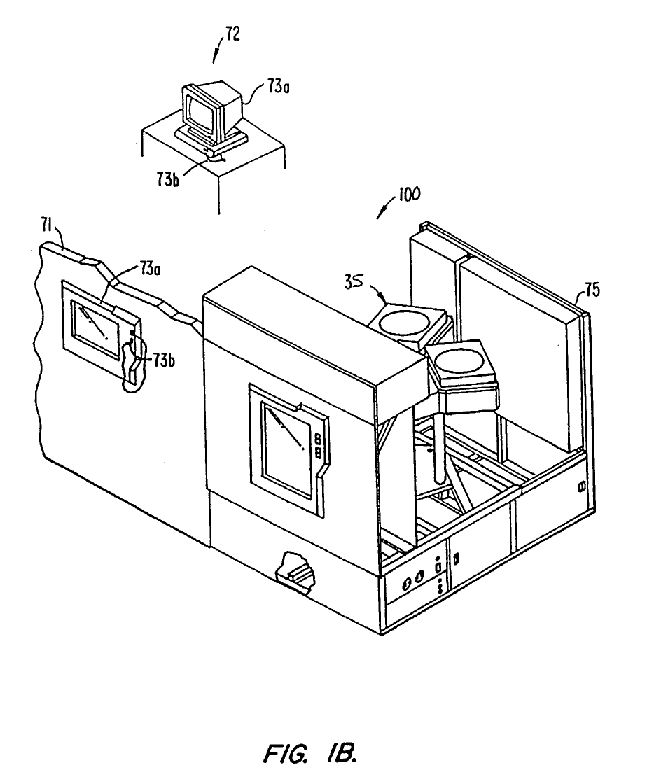

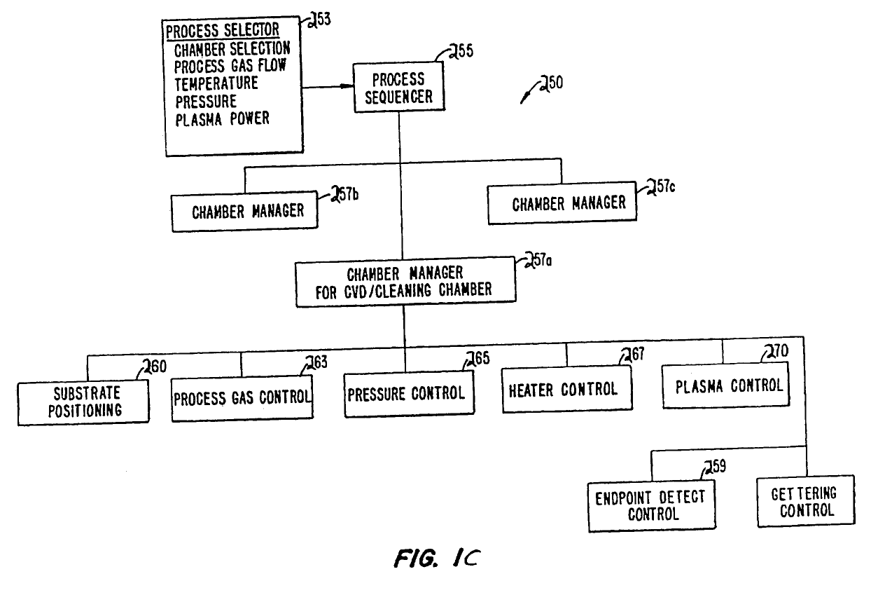

FIG. 1A is a simplified diagram of a chemical vapor deposition (“CVD”) system 100 according to the present invention. This system is suitable for performing thermal, sub-atmospheric CVD (“SACVD”) processes, as well as other processes, such as reflow, drive-in, cleaning, etching, and gettering processes. Multiple-step processes can also be performed on a single substrate or wafer without removing the substrate from the chamber. The major components of the system include, among others, a vacuum chamber 35 that receives process and other gases from a gas delivery system 31, a vacuum system 112, a remote microwave plasma system 155, and a system controller 61. These and other components are described below in order to understand the present invention.

The CVD apparatus 100 includes an enclosure assembly 201 housing a vacuum chamber 35 with a gas reaction area 21. A gas distribution plate 106 is provided above the central gas reaction area 21 for dispersing reactive gases and other gases, such as purge gases, through perforated holes in the gas distribution plate 106 to a wafer (not shown) that rests on a vertically movable heater 110 (also referred to as a wafer support pedestal). The heater 110 can be controllably moved between a lower position, where a wafer can be loaded or unloaded, for example, and a processing position closely adjacent to the gas distribution plate 106, indicated by a dashed line 113, or to other positions for other purposes, such as for an etch or cleaning process. A center board (not shown) includes sensors for providing information on the position of the wafer.

The heater 110 includes an electrically resistive heating element (not shown) enclosed in a ceramic. The ceramic protects the heating element from potentially corrosive chamber environments and allows the heater to attain temperatures up to about 600° C. or even higher. In an exemplary embodiment, all surfaces of the heater 110 exposed to the vacuum chamber 35 are made of a ceramic material, such as aluminum oxide (Al₂O₃ or alumina) or aluminum nitride.

Reactive and carrier gases are supplied into a gas mixing manifold (also called a gas mixing box or block) 37, where they are preferably mixed together and delivered to the gas distribution plate 106. The gas mixing box 37 may comprise a dual input mixing block coupled to a gas delivery system 31 and to a cleaning/etch gas conduit 147. A valve 280 operates to admit or seal gas or plasma from the gas conduit 147 to the gas mixing block 37. The gas conduit 147 receives gases from an integral remote microwave plasma system 155, which has an inlet 157 for receiving input gases. During deposition processing, gas supplied to the plate 106 is vented toward the wafer surface where it may be uniformly distributed radially across the wafer surface, typically in a laminar flow.

Purging gas may be delivered into the vacuum chamber 35 from the plate 106 and/or an inlet port or tube (not shown in FIG. 1A) through the bottom wall of enclosure assembly 201. The purging gas flows upward from the inlet port past the heater 110 and to an annular pumping channel 40. An exhaust system then exhausts the gas (as indicated by arrows 22) into the annular pumping channel 40 and through an exhaust line 114 to a vacuum system 112, which includes a vacuum pump (not shown). Exhaust gases and entrained particles are drawn from the annular pumping channel 40 through the exhaust line 114 at a rate controlled by a throttle valve system 63.

The remote microwave plasma system 155 can produce a plasma for selected applications, such as chamber cleaning or etching native oxide or residue from a process wafer. Plasma species produced in the remote plasma system 155 from precursors supplied via the input line 157 are sent via the conduit 147 for dispersion through the plate 106 to the vacuum chamber 35. Precursor gases for a cleaning application may include fluorine, chlorine, and other reactive elements. The remote microwave plasma system 155 also may be adapted to deposit plasma-enhanced CVD films by selecting appropriate deposition precursor gases for use in the remote microwave plasma system 155.

The system controller 61 controls activities and operating parameters of the deposition system. The processor 50 executes system control software, such as a computer program stored in a memory 70 coupled to the processor 50. Preferably, the memory 70 may be a hard disk drive, but of course the memory 70 may be other kinds of memory, such as read-only memory or flash memory. In addition to a hard disk drive (e.g., memory 70), the CVD apparatus 100 in a preferred embodiment includes a floppy disk drive and a card rack (not shown).

The processor 50 operates according to system control software, which includes sets of instructions that dictate the timing, mixture of gases, chamber pressure, chamber temperature, microwave power levels, susceptor position, and other parameters of a particular process. Other computer programs such as those stored on other memory including, for example, a floppy disk or another computer program product inserted in a disk drive or other appropriate drive, may also be used to operate the processor 50 to configure the CVD system 10 into various apparatus.

The processor 50 has a card rack (not shown) that contains a single-board computer, analog and digital input/output boards, interface boards and stepper motor controller boards. Various parts of the CVD system 100 conform to the Versa Modular European (VME) standard which defines board, card cage, and connector dimensions and types. The VME standard also defines the bus structure having a 16-bit data bus and 24-bit address bus.

FIG. 1B is a simplified diagram of a user interface in relation to the CVD apparatus chamber 35. The CVD apparatus 100 includes one chamber of a multichamber system. Wafers may be transferred from one chamber to another for additional processing. In some cases the wafers are transferred under vacuum or a selected gas. The interface between a user and the processor is via a CRT monitor 73a and a light pen 73b. A mainframe unit 75 provides electrical, plumbing, and other support functions for the CVD apparatus 100. Exemplary mainframe units compatible with the illustrative embodiment of the CVD apparatus are currently commercially available as the PRECISION 5000® and the CENTURA® 5200 systems from APPLIED MATERIALS, INC. of Santa Clara, Calif.

In the preferred embodiment two monitors 73a are used, one mounted in the clean room wall 71 for the operators, and the other behind the wall 72 for the service technicians. Both monitors 73a simultaneously display the same information, but only one light pen 73b is enabled. The light pen 73b detects light emitted by the CRT display with a light sensor in the tip of the pen. To select a particular screen or function, the operator touches a designated area of the display screen and pushes the button on the pen 73b. The touched area changes its highlighted color, or a new menu or screen is displayed, confirming communication between the light pen and the display screen. Of course, other devices, such as a keyboard, mouse, or other pointing or communication device, may be used instead of or in addition to the light pen 73b to allow the user to communicate with the processor.

FIG. 1C is an illustrative block diagram of the hierarchical control structure of the system control software, computer program 250, according to a specific embodiment. A processes for depositing a film, performing a clean, or performing reflow or drive-in can be implemented using a computer program product that is executed by the processor 50. The computer program code can be written in any conventional computer readable programming language, such as 68000 assembly language, C, C++, Pascal, Fortran, or other language.

Suitable program code is entered into a single file, or multiple files, using a conventional text editor and is stored or embodied in a computer-usable medium, such as the system memory.

If the entered code text is in a high-level language, the code is compiled, and the resultant compiler code is then linked with an object code of precompiled WINDOWS™ library routines. To execute the linked compiled object code, the system user invokes the object code, causing the computer system to load the code in memory, from which the CPU reads and executes code to configure the apparatus to perform tasks identified in the program.

A user enters a process set number and process chamber number into a process selector subroutine 253 by using the light pen to select a choice provided by menus or screens displayed on the CRT monitor. The process sets, which are predetermined sets of process parameters necessary to carry out specified processes, are identified by predefined set numbers. The process selector subroutine 253 identifies (i) the desired process chamber, and (ii) the desired set of process parameters needed to operate the process chamber for performing the desired process. The process parameters for performing a specific process relate to process conditions such as, for example, process gas composition and flow rates, temperature, pressure, plasma conditions such as magnetron power levels (and alternatively to or in addition to high- and low-frequency RF power levels and the low-frequency RF frequency, for embodiments equipped with RF plasma systems), cooling gas pressure, and chamber wall temperature. The process selector subroutine 253 controls what type of process (e.g. deposition, wafer cleaning, chamber cleaning, chamber gettering, reflowing) is performed at a certain time in the chamber. In some embodiments, there may be more than one process selector subroutine. The process parameters are provided to the user in the form of a recipe and may be entered utilizing the light pen/CRT monitor interface.

A process sequencer subroutine 255 has program code for accepting the identified process chamber and process parameters from the process selector subroutine 253, and for controlling the operation of the various process chambers. Multiple users can enter process set numbers and process chamber numbers, or a single user can enter multiple process set numbers and process chamber numbers, so process sequencer subroutine 255 operates to schedule the selected processes in the desired sequence. Preferably, the process sequencer subroutine 255 includes program code to perform the steps of (i) monitoring the operation of the process chambers to determine if the chambers are being used, (ii) determining what processes are being carried out in the chambers being used, and (iii) executing the desired process based on availability of a process chamber and the type of process to be carried out.

Conventional methods of monitoring the process chambers, such as polling methods, can be used. When scheduling which process is to be executed, the process sequencer subroutine 255 can be designed to take into consideration the present condition of the process chamber being used in comparison with the desired process conditions for a selected process, or the “age” of each particular user-entered request, or any other relevant factor a system programmer desires to include for determining scheduling priorities.

Once the process sequencer subroutine 255 determines which process chamber and process set combination is going to be executed next, the process sequencer subroutine 255 initiates execution of the process set by passing the particular process set parameters to a chamber manager subroutine 257a-c which controls multiple processing tasks in the process chamber according to the process set determined by the process sequencer subroutine 255. For example, the chamber manager subroutine 257a has program code for controlling CVD and cleaning process operations in the process chamber. Chamber manager subroutine 257 also controls execution of various chamber component subroutines which control operation of the chamber components necessary to carry out the selected process set. Examples of chamber component subroutines are substrate positioning subroutine 260, process gas control subroutine 263, pressure control subroutine 265, heater control subroutine 267, plasma control subroutine 270, endpoint detect control subroutine 259, and gettering control subroutine 269.

Depending on the specific configuration of the CVD chamber, some embodiments include all of the above subroutines, while other embodiments may include only some of the subroutines. Those having ordinary skill in the art would readily recognize that other chamber control subroutines can be included depending on what processes are to be performed in the process chamber.

In operation, the chamber manager subroutine 257a selectively schedules or calls the process component subroutines in accordance with the particular process set being executed. The chamber manager subroutine 257a schedules the process component subroutines much like the process sequencer subroutine 255 schedules which process chamber and process set are to be executed next. Typically, the chamber manager subroutine 257a includes monitoring various chamber components, determining which components need to be operated based on process parameters for the process set to be executed, and initiating execution of a chamber component subroutine responsive to the monitoring and determining steps.

Operation of particular chamber component subroutines will now be described with reference to FIGS. 1A and 1C. The substrate positioning subroutine 260 comprises program code for controlling chamber components that are used to load the substrate onto the heater 110 and, optionally, to lift the substrate to a desired height in the chamber to control the spacing between the substrate and the gas distribution manifold 106. When a substrate is loaded into the process chamber 35, the heater 110 is lowered to receive the substrate and then the heater 110 is raised to the desired height. In operation, the substrate positioning subroutine 260 controls movement of the heater 110 in response to process set parameters related to the support height that are transferred from the chamber manager subroutine 257a.

The process gas control subroutine 263 has program code for controlling process gas composition and flow rates. The process gas control subroutine 263 controls the state of safety shut-off valves, and also ramps the mass flow controllers up or down to obtain the desired gas flow rate. Typically, the process gas control subroutine 263 operates by opening the gas supply lines and repeatedly (i) reading the necessary mass flow controllers, (ii) comparing the readings to the desired flow rates received from the chamber manager subroutine 257a, and (iii) adjusting the flow rates of the gas supply lines as necessary. Furthermore, the process gas control subroutine 263 includes steps for monitoring the gas flow rates for unsafe rates, and activating the safety shut-off valves when a fault or an unsafe condition is detected. Alternative embodiments could have more than one process gas control subroutine, each subroutine controlling a specific type of process or specific sets of gas lines.

In some processes, an inert gas, such as nitrogen or argon, is flowed into the chamber to stabilize the pressure in the chamber before reactive process gases are introduced. For these processes, process gas control subroutine 263 is programmed to include steps for flowing the inert gas into the chamber for an amount of time necessary to stabilize the pressure in the chamber, and then the steps described above would be carried out.

Additionally, when a process gas is to be vaporized from a liquid precursor, such as TEOS, process gas control subroutine 263 would be written to include steps for bubbling a delivery gas such as helium through the liquid precursor in a bubbler assembly, or controlling a liquid injection system to spray or squirt liquid into a stream of carrier gas, such as helium, through the LFM. When a bubbler is used for this type of process, the process gas control subroutine 263 regulates the flow of the delivery gas, the pressure in the bubbler, and the bubbler temperature in order to obtain the desired process gas flow rates. As discussed above, the desired process gas flow rates are transferred to the process gas control subroutine 263 as process parameters.

Furthermore, the process gas control subroutine 263 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

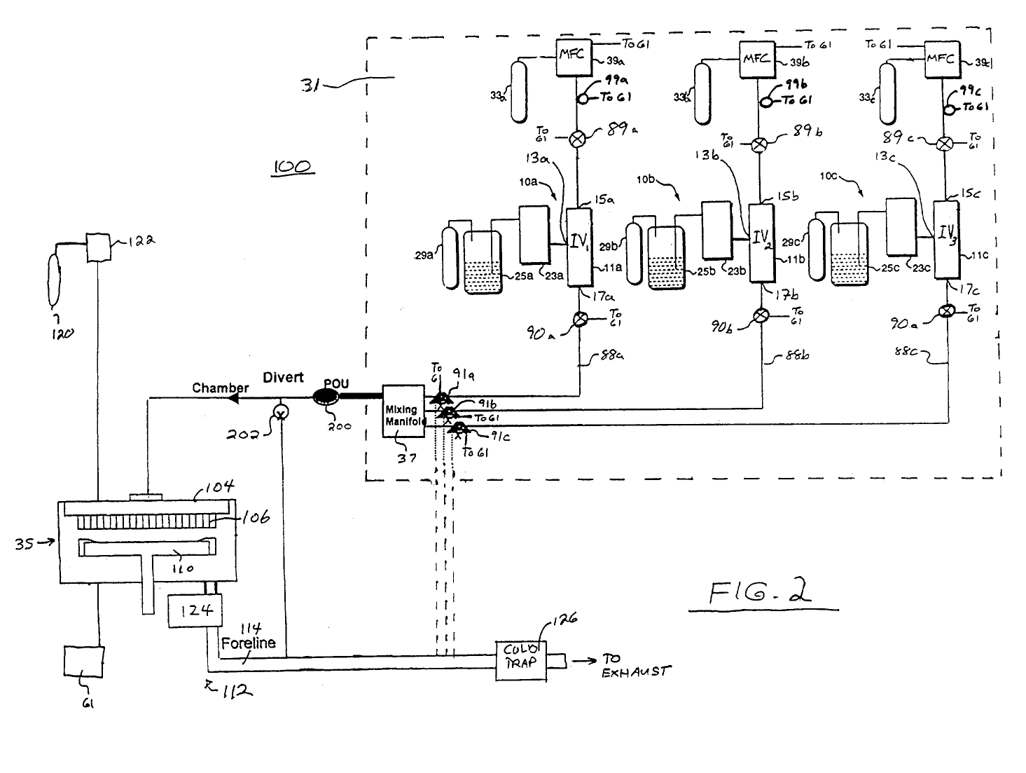

The process gas control subroutine 263 also includes steps for detecting clogging of components of the gas delivery system, and for alerting the operator or shutting down the system in the event of clogging. Specifically, as described in detail below in connection with FIG. 2, clogging of an injection valve or other component of the gas delivery system may be indicated by an elevated pressure upstream of the mass flow controller that provides a flow of gas to the injection valve. The pressure upstream of the mass flow controller can be monitored by the process gas control subroutine, with a fault indicated or system shut-down initiated where the pressure parameters reveal clogging of the line or valve.

The pressure control subroutine 265 comprises program code for controlling the pressure in the chamber by regulating the aperture size of the throttle valve in the exhaust system of the chamber. The aperture size of the throttle valve is set to control the chamber pressure at a desired level in relation to the total process gas flow, the size of the process chamber, and the pumping set-point pressure for the exhaust system. When the pressure control subroutine 265 is invoked, the desired or target pressure level is received as a parameter from the chamber manager subroutine 257a. The pressure control subroutine 265 measures the pressure in the chamber by reading one or more conventional pressure manometers connected to the chamber, compares the measure value(s) to the target pressure, obtains proportional, integral, and differential (“PID”) values corresponding to the target pressure from a stored pressure table, and adjusts the throttle valve according to the PID values.

Alternatively, the pressure control subroutine 265 can be written to open or close the throttle valve to a particular aperture size, i.e. a fixed position, to regulate the pressure in the chamber. Controlling the exhaust capacity in this way does not invoke the feedback control feature of the pressure control subroutine 265.

The heater control subroutine 267 comprises program code for controlling the current to a heating unit that is used to heat the substrate. The heater control subroutine 267 is also invoked by the chamber manager subroutine 257a and receives a target, or set-point, temperature parameter. The heater control subroutine 267 measures the temperature by measuring voltage output of a thermocouple located in the heater, comparing the measured temperature to the set-point temperature, and increasing or decreasing current applied to the heating unit to obtain the set-point temperature. The temperature is obtained from the measured voltage by looking up the corresponding temperature in a stored conversion table, or by calculating the temperature using a fourth-order polynomial. The heater control subroutine 267 includes the ability to gradually control a ramp up or down of the heater temperature. This feature helps to reduce thermal cracking in the ceramic heater. Additionally, a built-in fail-safe mode can be included to detect process safety compliance, and can shut down operation of the heating unit if the process chamber is not properly set up.

II. Gas Delivery System

FIG. 2 is a schematic diagram of an embodiment of a chemical vapor deposition (CVD) system 100 including a gas delivery system 31 in accordance with the present invention. Gas delivery system 31 is in fluid communication with processing chamber 35 through mixing manifold 37. In the example of FIG. 2, the processing chamber 35 is a CVD chamber configured to deposit silicon dioxide by flowing vaporized TEPO, tetraethyl orthosilicate (TEOS), and tetraethyl borate (TEB) into the processing chamber 35. However, embodiments in accordance with the present invention are not limited to this specific application, and may include one, two, four, or an even greater number of separate, devoted lines for delivering a variety of gases and vaporized liquids.

Chemical vapor deposition (CVD) system 100 generally includes a chamber 35, a chamber lid 104 having a gas distributor 106, with the gas delivery system 31 fluidly connected to gas distributor 106 to deliver one or more processing gases into chamber 35. A substrate support member 110 is disposed in the chamber. A vacuum exhaust system 112 is connected to a gas outlet or foreline 114 of the chamber, and a system controller 61 is connected to control operation of the CVD system. Specific examples of CVD systems utilizing gas delivery apparatuses and methods in accordance with embodiments of the present invention include the Ultima HDP-CVD™ chamber/system and the DXZ™ chamber/system, which are available from Applied Materials, Inc. of Santa Clara, Calif.

The substrate support member 110 is typically made of a ceramic or aluminum nitride (AlN) and may include a heater such as a resistive heating coil disposed inside the substrate support member, and may also include substrate chucking mechanisms for securely holding a substrate, such as a vacuum chuck or an electrostatic chuck. The gas distributor 106 may comprise a showerhead type gas distributor or a plurality of injection nozzles, for providing a uniform process gas distribution over a substrate disposed on the substrate support member 110. A temperature control system, such as a resistive heating coil and/or thermal fluid channels, may be disposed in thermal connection with the lid and the gas distributor 106. The temperature control system maintains the temperature of the gas distributor 106 within a desired range throughout processing. While gas distributor 106 is fluidly connected to the gas delivery system 31, gas distributor 106 may also be fluidly connected to one or more additional gas sources 120 through one or more additional mass flow controllers 122.

The exhaust system 112 includes one or more vacuum pumps 124, such as a turbomolecular pump, connected to exhaust gases from and maintain vacuum levels in the chamber 102. The one or more vacuum pumps 124 are connected to the foreline 114 for exhausting gases through a valve such as a gate valve. One or more cold traps 126 may be disposed on foreline 114 to remove or condense particular gases exhausted from the chamber.

Gas delivery system 31 comprises three processing liquid vaporization stages 10a-c in fluid communication with processing chamber 35 through devoted delivery lines 88a-c respectively. First stage 10a comprises a first injection valve 11a coupled to a source of liquid TEB 25a via a first liquid flow meter 23a. Second stage 10b comprises a second injection valve 11b coupled to a source of liquid TEOS 25b via a second liquid flow meter 23b. Third stage 10c comprises a third injection valve 11c coupled to a source of liquid TEPO 25c via a third liquid flow meter 23c. Each source of processing liquid 25a-c is coupled to a respective source of pressurized helium 29a-c.

The gas delivery system of FIG. 2 supplies carrier gas to each vaporization stage from separate carrier gas sources 33a-c through carrier gas delivery lines controlled by separate mass flow controllers (MFCs) 39a-c respectively. Each mass flow controller is in communication with system controller 61, allowing for control over the mass flow controller.

Equation (I) governs the rate of gas flow through the injection valves of the vaporization stages:

$$q = {N}_{2} {C}_{{vP}_{u}} ( 1 - \frac{2 ( {p}_{u} - {p}_{d} )}{3 {p}_{u}} ) \sqrt{\frac{{p}_{u} - {p}_{d}}{{p}_{u} {G}_{g} {T}_{u}}} \qquad ( I )$$

where:

q=flow rate;

N₂=constant for units;

C_{ν}=flow coefficient;

Pᵤ=upstream pressure;

P_{d}=down stream pressure;

G_{g}=gas specific gravity; and

Tᵤ=absolute upstream pressure.

Certain variables of equation (I) are constant under typical operating conditions. For example, the flow rate (q) of the carrier gas may be maintained constant by the mass flow controller, and the downstream pressure at the process chamber (pd) may be maintained constant by the throttle valve. The N₂, G_{g} and Tᵤ variables of Equation (I) may also be constant. Under conditions as just described, clogging of any injection valve will cause the flow coefficient (Cᵥ) to fall and the upstream pressure (pᵤ) to rise. Thus by monitoring the upstream pressure (pᵤ), clogging of the injection valve can be detected in-situ.

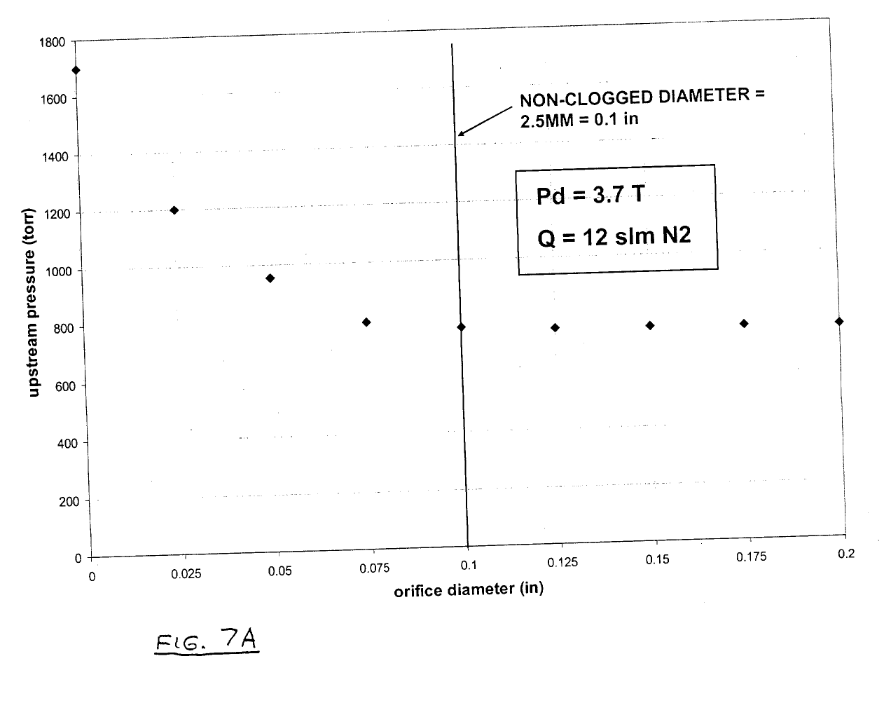

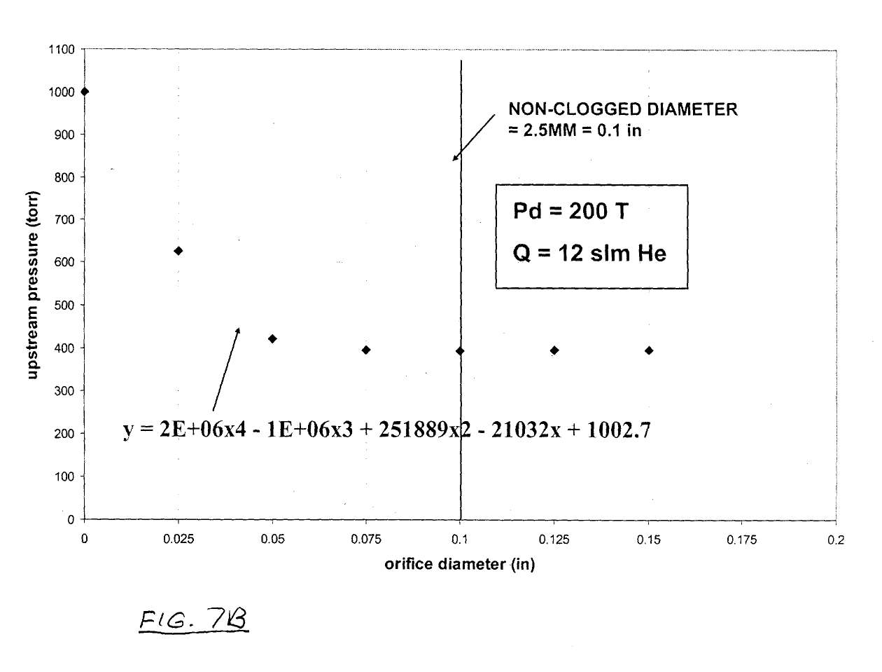

Correlation between clogging of an injection valve and an increase in pressure is shown in FIGS. 7A and 7B, which plot pressure upstream of an injection valve versus the diameter of the orifice in the injection valve through which gas is flowed. FIG. 7A plots the correlation between upstream pressure and orifice diameter for nitrogen gas flowed at a rate of 12 slm into a chamber having a downstream pressure of 3.7 Torr. FIG. 7B plots the correlation between upstream pressure and orifice diameter for helium gas flowed at a rate of 12 slm into a chamber having a downstream pressure of 200 Torr. Both figures reflect an exponential increase in pᵤ where the diameter of the orifice falls below a minimum.

Embodiments of the present invention accordingly exploit this relationship between upstream pressure and effective orifice diameter in order to reveal clogging. Thus in the embodiment of FIG. 2, pressure transducers 99a-c are positioned on delivery lines 88a-c, between mass flow controllers 39a-c and injection valves 15a-c, respectively. There are a variety of different transducer types which may be relied upon to detect clogging in accordance with embodiments of the present invention. One example is the family of BARATRON® type 740 and 750 industrial pressure transducers manufactured by MKS Instruments, Inc., of Andover, Mass.

Pressure transducers 99a-c are in communication with controller 61 to provide data regarding possible clogging of the injection valves positioned downstream. Specifically, memory 50 of controller 61 may include a computer-readable program embodied therein for receiving readings from the pressure transducers, and for comparing the readings to previously established pressure set point values. The computer-readable program may include computer instructions for comparing a pressure upstream of one of the mass flow controllers relative to a setpoint pressure, and also include instructions for automatically alerting an operator to a possible fault and/or halting operation of the apparatus when the pressure upstream of the first or second mass flow controllers deviates by a predetermined amount from the setpoint pressure, indicating possible obstruction of an orifice in the injection valve and clogging of the vaporization stage.

Returning to FIG. 2, the carrier gas flowed from devoted carrier gas sources 33a-c vaporizes processing liquid within stages 10a-c of gas delivery system 31, respectively. Flow into and out of vaporization stages 10a-c is controlled by valves positioned on the gas delivery lines both upstream and downstream of the vaporization stages. Specifically, upstream shut off valves 89a-c control the flow of carrier gas through lines 88a-c to vaporization stages 10a-c, respectively. Final valves 90a-c positioned downstream from vaporization stages 10a-c respectively, govern the flow of the carrier gas/vaporized liquid mixture from vaporization stages 10a-c to the mixing manifold 37.

The outlet of the first devoted delivery line 88a, the outlet of the second devoted delivery line 88b, and the outlet of the third devoted delivery line 88c, join at a mixing manifold 37 positioned downstream of injection valves 11a, 11b, and 11c.

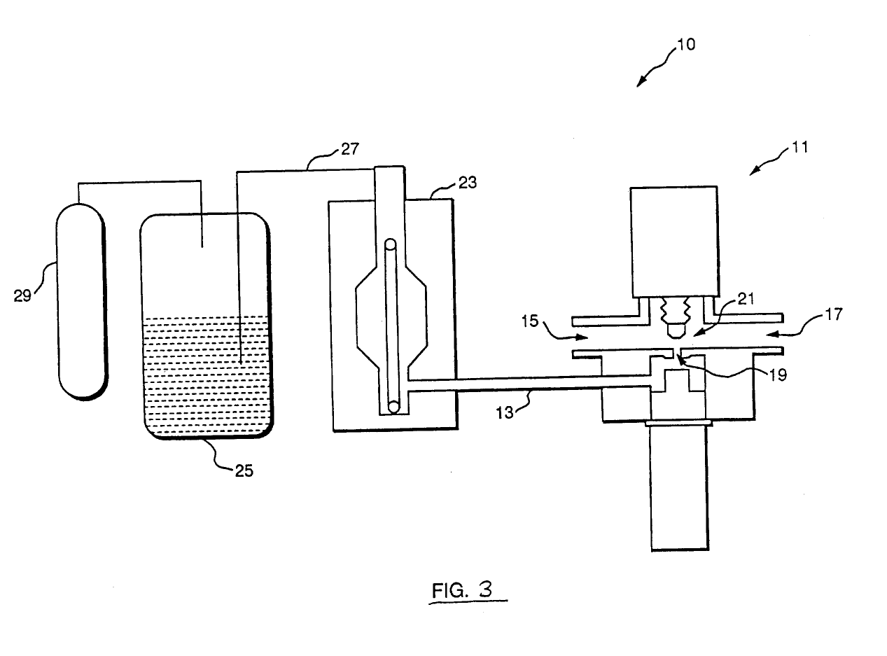

During operation, an inert carrier gas such as helium flows from the gas sources 33a-c into flow controllers 39a-c respectively, and the flow controllers 39a-c are set at a first flow rate. Within each vaporization stage 10a-c, the processing liquid is vaporized as described below in conjunction with FIG. 3. Thus, a mixture of vaporized TEB and helium flows from outlet 17a of the first injection valve 11a through final valve 90a and divert valve 91a to the mixing manifold 37. A mixture of vaporized TEOS and helium flows from outlet 17b of the second injection valve 11b through final valve 90b and divert valve 91b to the mixing manifold 37, and a mixture of vaporized TEPO and helium flows from outlet 17c of the third injection valve 11c through final valve 90c and divert valve 91c to the mixing manifold 37.

The combined vaporized TEB, TEOS, TEPO, and the helium flowed into the mixing manifold 37 experiences mixing, with any resulting solid particulate matter is removed by point-of-use (POU) filter 200. While not limited to any particular pore size or manufacturer, an example of a filter utilized in this particular application is the 0.003 μm pore filter manufactured for semiconductor fabrication applications by Millipore of Bedford, Mass.

After passing through filter 200, the filtered mixture then flows to the processing chamber 35 where the chamber pressure and temperature causes the TEB, TEOS and TEPO to react to form a doped silicon dioxide layer on a substrate (not shown) positioned within the processing chamber 35. Divert valve 202 is positioned immediately downstream of point-of-use filter 200. Activation of divert valve 202 shunts the mixture of processing components into foreline 114 and away from processing chamber 35 for disposal.

FIG. 3 is a diagrammatic side elevational view of a generic vaporization stage 10 of the gas distribution apparatus 31 shown in FIG. 2. Vaporization stage 10 comprises a conventional injection valve 11 that comprises a processing liquid inlet 13 for inputting a processing liquid, a carrier gas inlet 15 for inputting an inert carrier gas, and an outlet 17 for outputting a vaporized processing liquid/carrier gas mixture. Within each injection valve 11, the processing liquid inlet 13 terminates at an orifice 19 leading to a central gas reaction area 21 where the processing liquid inlet 13, the carrier gas inlet 15, and the outlet 17 meet. The injection valve 11 is configured such that the relative sizes of the orifice 19 and the central region 21, and the pressures, flow rates and relative direction of the processing liquid and carrier gas flow cause a pressure drop within the central region 21, as is conventionally known in the art. This pressure drop causes processing liquid supplied to the processing liquid inlet 13 to vaporize as it passes from the processing liquid inlet 13, through the orifice 19 to the central region 21. In order to facilitate vaporization, the orifice 19 is small, and thus may be vulnerable to clogging by generated residual generated solid material.

Outside the injection valve 11, the processing liquid inlet 13 is coupled to a liquid flow meter (LFM) 23 of the vaporization stage 10 which controls the flow rate of processing liquid traveling to the injection valve 11. The liquid flow meter 23 also is coupled via line 27 to a source of processing liquid 25 within the vaporization stage 10, which in turn is coupled to a source of pressurized helium 29.

In operation, the pressurized helium flow forces the processing liquid from the processing liquid source 25 through line 27 to the liquid flow meter 23. The liquid flow meter 23 controls the flow rate of the processing liquid as it travels from liquid flow meter 23 through the processing liquid inlet 13 and the orifice 19 to the central region 21 of the injection valve 11. A pressurized carrier gas, such as helium, flows through the carrier gas inlet 15 into the central region 21.

The processing liquid vaporizes and mixes with the carrier gas as the processing liquid enters the central region 21, due to the pressure decrease experienced as the processing liquid travels from the orifice 19 to the central region 21. The combined vaporized processing liquid/carrier gas flows from the injection valve 11 via the outlet 17.

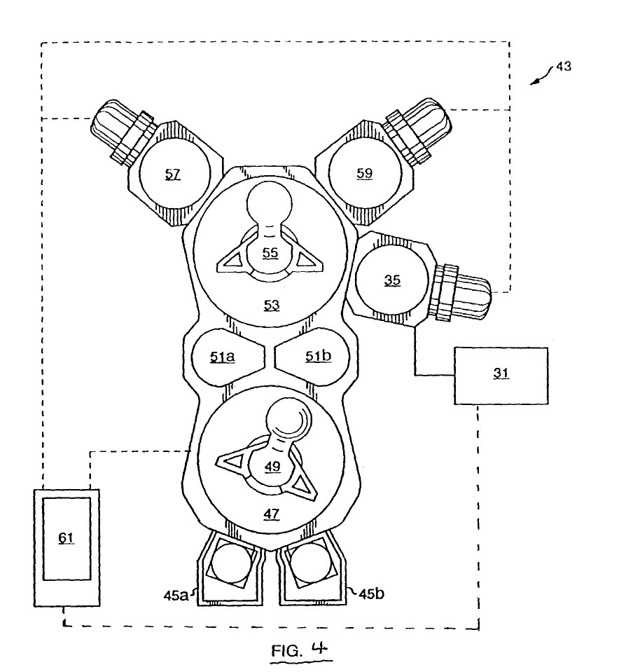

FIG. 4 is a top plan view of an automated tool 43 for fabricating semiconductor devices. The tool 43 comprises a pair of load locks 45a, 45b, and a first wafer handler chamber 47 containing a first wafer handler 49. The first wafer handler chamber 47 is operatively coupled to the pair of load locks 45a, 45b and to a pair of pass-through chambers 51a, 51b. The pair of pass-through chambers 51a, 51b are further coupled to a second wafer handler chamber 53 (e.g., a transfer chamber), containing a second wafer handler 55, and to a plurality of processing chambers 57, 59. Most importantly, the second wafer handler chamber 53 is coupled to the processing chamber 35 of FIG. 1 which is further coupled to the inventive gas delivery system 31.

The entire tool 43 is controlled by a controller 61 (which comprises a microprocessor and a memory not shown in FIG. 4) having a program therein, which controls semiconductor wafer transfer among the load locks 45a, 45b, the pass-through chambers 51a, 51b, and the processing chambers 57, 59, 35, and which controls processing therein. As shown in FIG. 2, controller 61 is also in communication with various components of the gas delivery system 31, including mass flow controllers 39a-c, pressure sensors 99a-c, final valves 90a-c, and diversion valves 91a-c.

The controller program and the overall configuration of the tool 43 is designed for optimal productivity. A clogged gas delivery system within such a tool is particularly costly, as it can affect the productivity of the entire tool 43, including the plurality of processing chambers contained therein. Thus, by employing the gas delivery system 31 in accordance with an embodiment of the present invention, the value of the automated semiconductor processing tool 43 increases significantly.

Embodiments of methods and systems in accordance with the present invention offer a number of advantages over conventional liquid vaporization gas delivery techniques. One advantage is rapid and reliable detection of clogging of injection valves.

Specifically, conventional gas delivery techniques typically utilize ex situ means for monitoring injection valves for clogging. Specifically, following a processing step, the thickness of a deposited layer is measured and compared with expected values. A reduction in the thickness of the deposited layer may reveal a reduced flow of a vaporized liquid precursor material, and hence partial or complete obstruction or clogging of an injection valve. Such detection of clogging after-the-fact is relatively expensive, as batches of wafers already processed and bearing the deposited layer of diminished thickness must be discarded.

By contrast, embodiments in accordance with the present invention utilize real-time monitoring of pressures to allow detection of the clogging of injection valves in-situ. Such pressure monitoring techniques allow rapid detection of clogging, such that at a minimum only the wafers actually being processed during the clogging event are affected and need to be scrapped before the situation is corrected. Moreover, in some cases the rapidity and precision of the indication of clogging may allow the tool operator to take corrective action and thereby prevent even those wafers being processed from falling outside the specified tolerance range.

The foregoing description discloses only specific embodiments in accordance with the present invention, and modifications of the above disclosed apparatuses and methods falling within the scope of the invention will be apparent to those of ordinary skill in the art. For example, the present invention may reduce clogging within any processing environment wherein mixed processing constituents may react to form an undesirable product that can clog the various components within a gas delivery system.

For example, while the specific embodiment shown and described above in connection with FIGS. 1A-2 focuses upon delivery of three vaporized liquids to a processing chamber, the present invention is not limited to the specific delivery of three vaporized processing liquids, nor to delivery of the specific processing liquids described (TEB, TEPO, TEOS). Other liquid processing materials which may be vaporized prior to processing in the fabrication of semiconductors include, but are not limited to, titanium tetrachloride (TiCl₄), trimethylsilane (SiH(CH₃)₃), tetramethylsilane (Si(CH₃)₄), tetramethylcyclotetrasiloxane (TOMCATS), dimethyldimethoxysilane (Z2DM), trimethyl phosphite (TMPI), trimethylphosphate (TMPO), trimethylborate (TMB), phosphorus oxychloride (POCl₃), boron tribromide (BBr₃), bis(tertiary-butylamino)silane (BTBAS), tantalum pentaethoxide (TAETO), tantalum tetraethoxide dimethylaminoethoxide (TAT-DMAE), tert-butylimino tris(diethylamino) tantalum (TBTDET), tetrakis-diethylamino titanium (TDEAT), and tetrakis-dimethylamino titanium (TDMAT).

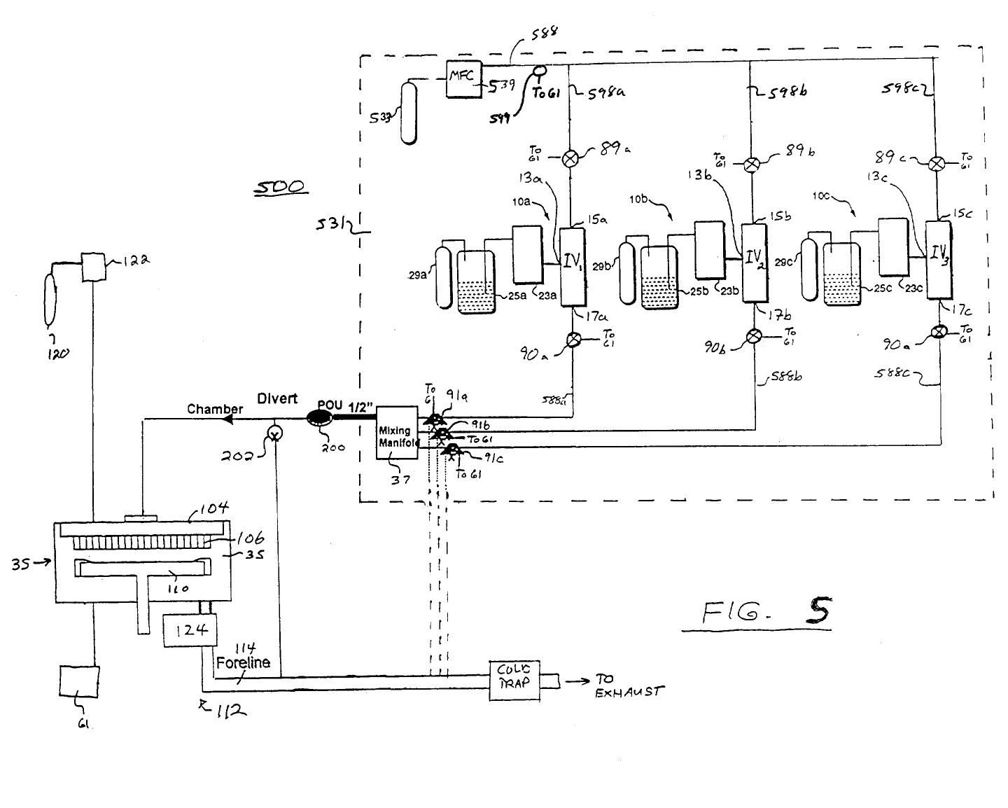

And while the embodiment of FIG. 2 shows the use of multiple pressure transducers located upstream of different parallel branches of a gas delivery system, this particular configuration is not required by the present invention. For example, FIG. 5 shows a simplified schematic view of a first alternative embodiment of a chemical vapor deposition (CVD) system 500 including a gas delivery system 531 in accordance with the present invention, wherein a single carrier gas source 533 supplies a flow of carrier gas to three injection valves 511a-c arranged in parallel along branches 598a-c of carrier gas flow line 588. Clogging of any one of the three injection valves 511 a-c may be detected by monitoring the pressure indicated by the single pressure transducer 599. Specifically, the setpoint of transducer 599 may be based upon unobstructed flow through each of the parallel injection valves, with an increase in detected pressure revealing a potential clogging event in any one of the injection valves. The embodiment shown in FIG. 5 does not necessarily allow for precise identification of the particular valve which is experiencing clogging. However, the embodiment of FIG. 5 may be advantageous because it requires purchase, maintenance, and monitoring of only a single carrier gas source, mass flow controller, and pressure transducer, and may readily be adapted for use with existing gas delivery systems having the disclosed configuration.

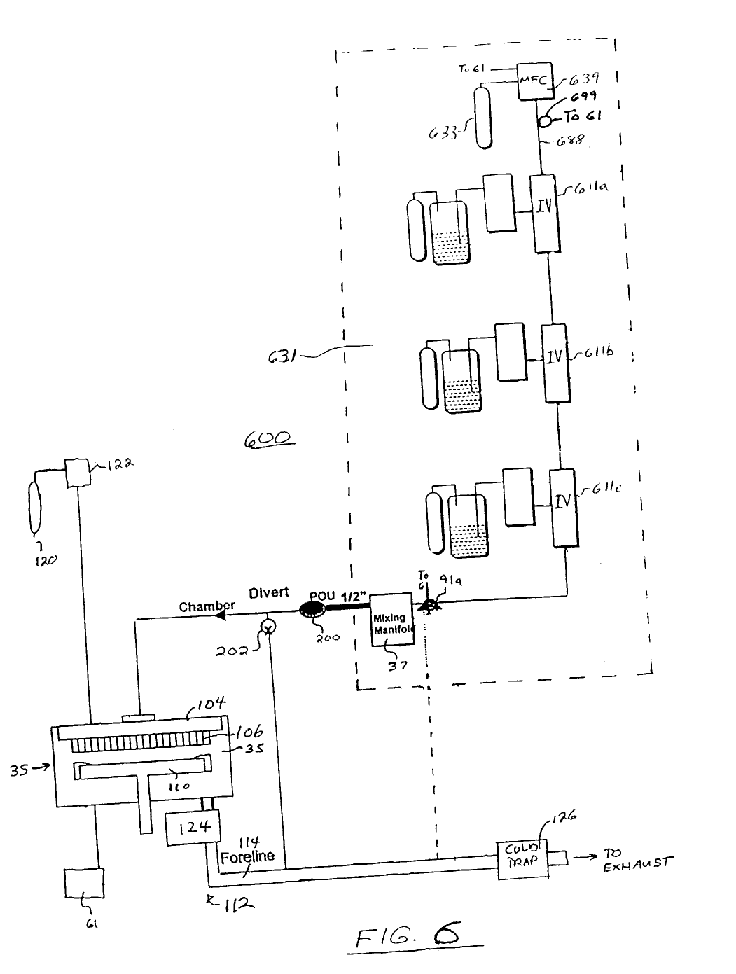

Moreover, embodiments in accordance with the present invention are not limited to detecting clogging in a set of injection valves arranged in parallel. FIG. 6 shows a simplified schematic view of a second alternative embodiment of a chemical vapor deposition (CVD) system 600 including a gas delivery system 631 in accordance with the present invention, wherein single pressure transducer 699 is positioned on carrier gas flow line 688 between mass flow controller 639 and three serially-arranged injection valves 611a-c. Clogging of any one of the three serial injection valves 611a-c may be detected by monitoring the pressure indicated by transducer 699. Specifically, the setpoint of transducer 699 is based upon unobstructed flow through the entire series of three injection valves, with an increase in detected pressure revealing a potential clogging event in one of the valves. Again, while the embodiment shown in FIG. 6 does not necessarily allow for precise identification of the particular valve of the series which is experiencing clogging, this embodiment may be advantageous because it requires the purchase, maintenance, and monitoring of only a single carrier gas source, mass flow controller, and pressure transducer, and may readily be adapted for use with existing gas delivery systems having the disclosed configuration.

It will be understood that the exemplary gas delivery system may contain additional components (e.g., valves, flow meters, etc.), and the various components of the gas delivery system can be made with reduced nickel content and increased chromium content to further reduce formation of residues. And although the benefits of the inventive gas delivery system are most dramatic when used with injection valves, other vaporization mechanisms such as bubblers may also be employed.

Finally, gas panel components of systems and methods in accordance with embodiments of the present invention may take the form of assemblies of discrete lines, valves, inlets, outlet, and transducers. Alternatively however, gas panels utilized in accordance with embodiments of the present invention may be formed from integral blocks having flow lines, chambers, inlets, outlets, and other ports formed therein by machining or other fabrication methods.

Accordingly, while the present invention has been disclosed in connection with the preferred embodiments thereof, it should be understood that other embodiments may fall within the spirit and scope of the invention, as defined by the following claims.

What is claimed is:

1. A system for providing a vaporized liquid precursor to a semiconductor processing chamber, the apparatus comprising:
a mass flow controller in fluid communication with a pressurized carrier gas source through a carrier gas flow line;
a liquid precursor injection valve, the liquid precursor injection valve in fluid communication with the mass flow controller through the carrier gas flow line, in fluid communication with a liquid precursor source through a first line, and in fluid communication with a processing chamber through a delivery line; and
a pressure transducer in communication with the carrier gas flow line and configured to detect a pressure within the carrier gas flow line between the mass flow controller and the injection valve.

2. The system of claim 1 further comprising a processor in communication with the pressure transducer and configured to detect a deviation of the detected pressure from a setpoint pressure reflecting an unobstructed flow of carrier gas and vaporized liquid precursor through the injection valve.

3. The system of claim 2 further comprising a memory coupled to the processor and comprising a computer-readable medium having a computer-readable program embodied therein, the computer-readable program including:
(i) a first set of computer instructions for comparing the detected pressure with the setpoint pressure; and
(ii) a second set of instructions for at least one of automatically alerting an operator to a possible injection valve clogging event, and halting the flow of vaporized liquid precursor material to the processing chamber, when the detected pressure deviates by a predetermined amount from the setpoint pressure.

4. The system of claim 2 further comprising a second liquid precursor injection valve in fluid communication with a second liquid precursor source, the processing chamber in fluid communication with the first injection valve through the second injection valve, wherein the setpoint pressure further reflects an unobstructed flow of carrier gas and fully vaporized first and second liquid precursor through the second injection valve.

5. The system of claim 2 further comprising a second liquid precursor injection valve in fluid communication with a second liquid precursor source, the second liquid precursor injection valve in fluid communication with the pressurized carrier gas source through the mass flow controller and a branch of the carrier gas flow line, the second liquid precursor injection valve also in fluid communication with the processing chamber through a parallel delivery line, wherein the setpoint pressure further reflects an unobstructed flow of carrier gas and vaporized second liquid precursor through the second injection valve.

6. The system of claim 1 further comprising:
a second mass flow controller in fluid communication with a second pressurized carrier gas source through a second carrier gas flow line;
a second liquid precursor injection valve in fluid communication with the second mass flow controller through the second carrier gas flow line, in fluid communication with a second liquid precursor source through a first line, and in fluid communication with the processing chamber through a second delivery line; and
a second pressure transducer in communication with the carrier gas flow line and configured to detect a second pressure within the second carrier gas flow line between the second mass flow controller and the second injection valve.

7. The system of claim 6 wherein the first and second pressure transducers are in communication with a processor, and the processor is configured to detect at least one of,
deviation of the first detected pressure from a first setpoint pressure reflecting an unobstructed flow of carrier gas and vaporized first liquid precursor through the first injection valve, and
deviation of the second detected pressure from a second setpoint pressure reflecting an unobstructed flow of carrier gas and vaporized second liquid precursor through the second injection valve.

8. An apparatus for processing a semiconductor substrate comprising:
a processing chamber comprising a chamber lid and walls enclosing a substrate support, a gas distributor, and a vacuum exhaust connected to a chamber outlet;
a gas delivery system in fluid communication with the gas distributor, the gas delivery system comprising,
a mass flow controller in fluid communication with a pressurized carrier gas source through a carrier gas flow line,
a liquid precursor injection valve in fluid communication with the mass flow controller through the carrier gas flow line, in fluid communication with a liquid precursor source through a first line, and in fluid communication with a processing chamber through a delivery line, and
a pressure transducer in communication with the carrier gas flow line and configured to detect a pressure within the carrier gas flow line between the mass flow controller and the injection valve; and
a system controller comprising a memory and a processor, the processor in electrical communication with the pressure transducer.

9. The apparatus of claim 8 wherein the processor is configured to detect a deviation of the detected pressure from a setpoint pressure reflecting an unobstructed flow of carrier gas and vaporized liquid precursor through the injection valve.

10. The apparatus of claim 9 wherein the memory comprises a computer-readable medium having a computer-readable program embodied therein, the computer-readable program including:
(i) a first set of computer instructions for comparing the detected pressure with the setpoint pressure; and
(ii) a second set of instructions for at least one of automatically alerting an operator to possible clogging of the injection valve, and halting the flow of vaporized liquid precursor material to the processing chamber, when the detected pressure deviates by a predetermined amount from the setpoint pressure.

11. The apparatus of claim 9 wherein the gas delivery system further comprises a second liquid precursor injection valve in fluid communication with a second liquid precursor source, the processing chamber in fluid communication with the first injection valve through the second injection valve, wherein the setpoint pressure further reflects an unobstructed flow of carrier gas and fully vaporized first and second liquid precursor through the second injection valve.

12. The apparatus of claim 9 wherein the gas delivery system further comprises a second liquid precursor injection valve in fluid communication with a second liquid precursor source through a second line, the second liquid precursor injection valve in fluid communication with the pressurized carrier gas source through the mass flow controller and a branch of the carrier gas flow line, the second liquid precursor injection valve also in fluid communication with the processing chamber through a parallel delivery line, wherein the setpoint pressure further reflects an unobstructed flow of carrier gas and vaporized second liquid precursor through the second injection valve.

13. The apparatus of claim 8 wherein the gas delivery system further comprises:
a second mass flow controller in fluid communication with a second pressurized carrier gas source through a second carrier gas flow line;
a second liquid precursor injection valve in fluid communication with the second mass flow controller through the second carrier gas flow line, in fluid communication with a second liquid precursor source through a first line, and in fluid communication with the processing chamber through a second delivery line; and
a second pressure transducer in communication with the second carrier gas flow line and configured to detect a second pressure within the second carrier gas flow line between the second mass flow controller and the second injection valve.

14. The apparatus of claim 13 wherein the first and second pressure transducers are in communication with the processor, and the processor is configured to detect at least one of,
deviation of the first detected pressure from a first setpoint pressure reflecting an unobstructed flow of carrier gas and vaporized first liquid precursor through the first injection valve, and
deviation of a second detected pressure from a second setpoint pressure reflecting an unobstructed flow of carrier gas and vaporized second liquid precursor through the second injection valve.

15. The apparatus of claim 8 wherein the processing chamber comprises a chemical vapor deposition chamber.

16. A method of detecting clogging of an injection valve providing vaporized liquid precursor material to a semiconductor processing chamber, the method comprising:
detecting a pressure at a point between the injection valve and a mass flow controller providing a carrier gas to the injection valve.

17. The method of claim 16 further comprising:
storing a setpoint pressure value reflecting an unobstructed flow of gas through the injection valve; and
determining a deviation of the detected pressure from the setpoint pressure.

18. The method of claim 16 wherein the pressure is detected upstream of a serial arrangement of multiple injection valves.

19. The method of claim 16 wherein the pressure is detected upstream of a branch leading to parallel arrangement of multiple injection valves.

20. A vaporizing system comprising:
a liquid injection valve having first and second inlets and an outlet, the injection valve capable of receiving a carrier gas at the first inlet, receiving a liquid precursor at the second inlet, and delivering a mixture of vaporized liquid precursor and carrier gas through the outlet;
a carrier gas source;
a first gas line that couples the carrier gas source to the first inlet;
a liquid precursor source;
a second gas line that couples the liquid precursor source to the second inlet;
a mass flow controller operatively coupled to the first gas line; and
a pressure transducer coupled to the first gas line between the mass flow controller and the first inlet.

21. A method of delivering vaporized liquid to a processing chamber, the method comprising:
separately flowing a carrier gas and a liquid to an injection valve;
vaporizing liquid with the injection valve and combining the vaporized liquid with the carrier gas;
detecting pressure of the carrier gas upstream of the injection valve; and
comparing detected pressure versus a setpoint pressure value.
